(19) United States
(12) Patent Application Publication
(10) Pub. No.: US 2012/0012854 A1
(43) Pub. Date: Jan. 19, 2012

(54) ACTIVE MATRIX SUBSTRATE, DISPLAY PANEL, DISPLAY DEVICE, AND LASER IRRADIATION METHOD

(76) Inventor: Toshihiro Kaneko, Osaka (JP)

(21) Appl. No.: 13/260,027

(22) PCT Filed: Dec. 28, 2009
(86) PCT No.: PCT/JP2009/071760

§ 371 Date: Sep. 23, 2011

(30) Foreign Application Priority Data
Apr. 10, 2009 (JP) 2009-095754

(51) Int. Cl. H01L 29/786; H01L 21/768; H01L 21/268

(52) U.S. Cl. 257/72; 438/708; 438/662; 257/E29.273; 257/E21.347; 257/E21.585

(57) ABSTRACT

In an active matrix substrate (29), a part of the drain electrode (15) of a TFT (10), which corresponds to an auxiliary capacitor electrode (26), is overlapped with a capacitor signal line (25). The auxiliary capacitor electrode (26) includes a notch (27).

### TECHNICAL FIELD

The present invention relates to an active matrix substrate included in a display panel, the display panel itself, a display device including the display panel, and a method for irradiating the active matrix substrate with laser light.

### BACKGROUND ART

In display devices such as a liquid crystal display device, a switching element such as a TFT (thin film transistor) is used to control pixels. A substrate including such a switching element is referred to as an active matrix substrate and is adopted for use not only in a liquid crystal display device but also in various types of display devices.

It has been recently demanded that a display panel including such an active matrix substrate have a higher definition of several hundred thousand pixels or more. It is, however, extremely difficult to manufacture a display panel made up only of completely defect-free pixels. This is because, normally, in the manufacturing process of a display panel, due to dust, film forming conditions, or the like, a break in wiring, a short circuit, a characteristic failure of a switching element, or the like is likely to occur, causing some of numerous pixels to become dot-shaped or line-shaped defects (bright spots or the like). There has been conventionally proposed, however, a technique of correcting such a pixel defect (for example, Patent Document 1).

### List of Citations

### Patent Literature

### Patent Document 1: JP-A-2003-241155

### SUMMARY OF INVENTION

### Technical Problem

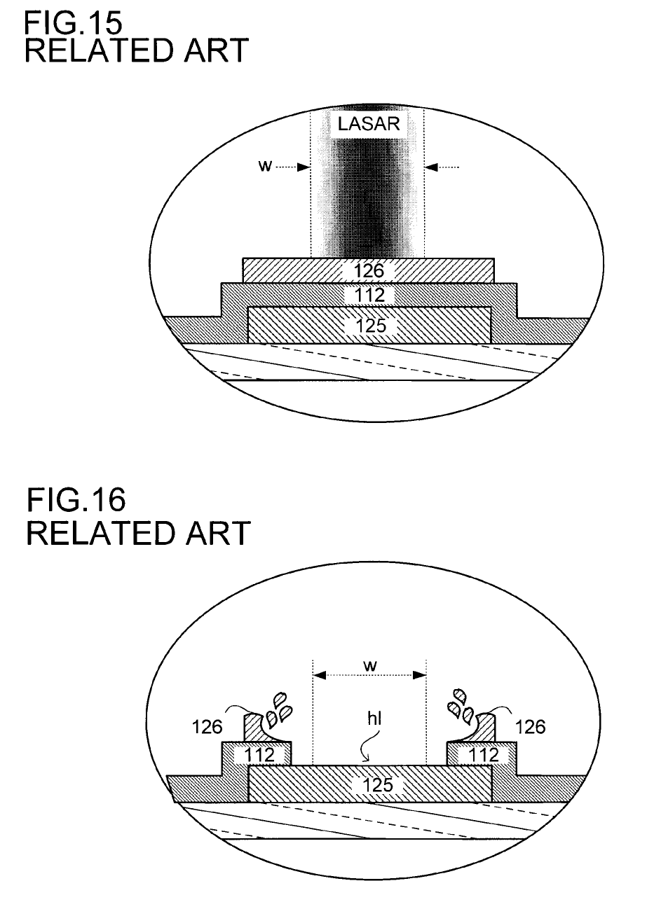

Referring to FIG. 14, one example of the technique of correcting a pixel defect is to cause a short circuit between a capacitor signal line 125 and a drain electrode 115 of a TFT 110. The capacitor signal line 125 overlaps a pixel (pixel electrode 124) representing each of pixels arranged in a matrix form, which is obtained by division along both a gate signal line 121 and a source signal line 122.

According to this technique, in order that a signal of the capacitor signal line 125 may be supplied to the pixel electrode 124, first, using laser light, the drain electrode 115 is cut at a part thereof between a tip end 126 thereof and the TFT 110 (the cut part is denoted by number 151). This securely cuts off the supply of a source signal to the pixel electrode 124.

Next, laser light irradiation is performed with respect to the tip end 126 (hereinafter, referred to as an auxiliary capacitor electrode 126) of the drain electrode 115, which overlaps the capacitor signal line 125 via a gate insulation film of the TFT 110 (a region irradiated with laser light is denoted by number 152). To be more specific, as shown in FIG. 15 that is a cross-sectional view taken on line b-b′ in the direction of arrows in FIG. 14, the capacitor signal line 125, a gate insulation film 112, and the auxiliary capacitor electrode 126, which are layered on top of another, are irradiated with laser light (a symbol w denotes a diameter of a laser spot sp). In this case, however, laser light intensity should be set appropriately by adjustment.

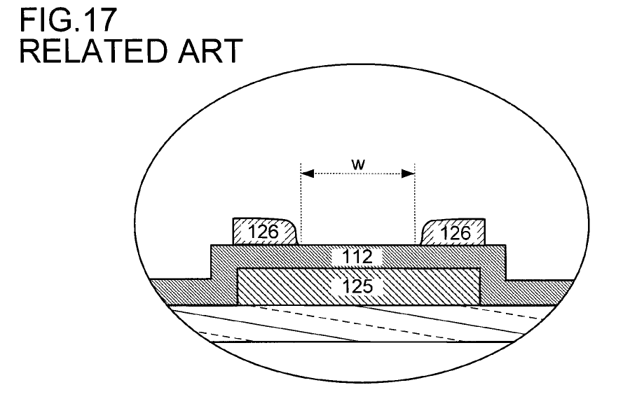

For example, if the laser light intensity is too high, as shown in FIG. 16, while a contact hole h1 is formed in the gate insulation film 112, the auxiliary capacitor electrode 126 is scattered, and thus a connection can hardly be established between the auxiliary capacitor electrode 126 and the capacitor signal line 125. On the other hand, if the laser light intensity is too low, as shown in FIG. 17, the contact hole h1 is not formed in the gate insulation film 112, and thus no connection is established between the auxiliary capacitor electrode 126 and the capacitor signal line 125. Hence, these cases do not bring about a phenomenon in which, in place of a source signal, a signal flowing through the capacitor signal line 125 is supplied to the pixel electrode 124 (i.e. a pixel), thus failing to solve the problem of a bright spot or the like.

The present invention has been made to solve the above-described problem. It is an object of the present invention to provide an active matrix substrate and so on that, when the active matrix substrate is irradiated with laser light, allow a member irradiated therewith to be supplied with various levels of laser energy, and a laser light irradiation method that allows such supply of various levels of laser energy.

### Solution to the Problem

An active matrix substrate includes: a substrate; a switching element mounted to the substrate; a gate signal line connected to a gate electrode of the switching element; a source signal line connected to a source electrode of the switching element; a drain electrode of the switching element; a partial electrode that is a part of the drain electrode; a capacitor signal line opposed to the partial electrode; and an insulation film interposed between the partial electrode and the capacitor signal line. In the active matrix substrate, a cutout or an opening is formed in the partial electrode.

The active matrix substrate incorporated in a display panel includes the switching element that controls each pixel. Based on a gate signal flowing through the gate signal line, the switching element supplies a pixel with a source signal flowing through the source signal line. In order that the source signal may be held, the partial electrode that is a part of the drain electrode is opposed to the capacitor signal line via the insulation film so as to form an auxiliary capacitor.

By the way, the above-described active matrix substrate may suffer from breakage of the switching element, in which case a pixel controlled by each of broken ones of the switching elements becomes, for example, a bright spot, leading to deterioration of picture quality. As a known method for minimizing the occurrence of a bright spot or the like, a part of the active matrix substrate is irradiated with laser light so as to be supplied with laser energy.

More specifically, in order that, in place of a source signal, a signal flowing through the capacitor signal line may be supplied to the pixel, laser light is applied to a part of the active matrix substrate so that the partial electrode and the capacitor signal line are fused together. When laser light irradiation is performed in this manner, in a case where the cutout or the opening is formed in the partial electrode in the active matrix substrate, a phenomenon can be brought about in which an opening portion of the cutout or the like passes one part of a laser spot therethrough, while a peripheral edge portion of the cutout or the like blocks the other part of the laser spot. Whether or not laser light is blocked in this manner makes the following difference.

For example, in order to prevent the partial electrode from being melted excessively to be scattered, the laser light intensity is set to a relatively low level. If the laser light intensity is too low, however, a contact hole for establishing a connection between the partial electrode and the capacitor signal line may not be formed in the insulation film covered with the partial electrode.

In a case, however, where the cutout or the like is formed in the partial electrode, laser light having such an intensity as not to cause excessive melting of the partial electrode is applied toward the cutout or the like, so that the peripheral edge portion of the cutout or the like, upon which a laser spot falls, is melted to a moderate degree. On the other hand, one part of the laser spot, which falls upon the opening portion of the cutout or the like, supplies laser energy to the gate insulation film without the partial electrode interposed therebetween, thus achieving loss-free supply of laser energy to the insulation film, so that a contact hole is formed.

That is, even in a case of using laser light having a constant intensity, a member irradiated with the laser light can be supplied with various levels of laser energy. As a result of this, the active matrix substrate configured as above allows the supply of laser energy suitable for required processing (for, for example, forming the contact hole in the insulation film or melting the partial electrode so that it is fused to the capacitor signal line). As a result of the above, a part of the partial electrode is fused securely to the capacitor signal line via the contact hole (the bottom line is that it is made possible for the pixel to receive the signal supply from the capacitor signal line, making it unlikely that the pixel becomes a bright spot).

By the way, normally, the laser light intensity of a laser spot is higher at a center portion thereof compared with that obtained at an edge portion thereof. For this reason, in a case where a part of the partial electrode and the capacitor signal line are fused together by laser light irradiation, preferably, the following configuration is adopted.

That is, preferably, a cutout width of the cutout or an opening width of the opening is set to be smaller than a diameter of a laser spot so that an opening portion of the cutout or an opening portion of the opening passes light of a center portion of the laser spot therethrough to guide it to the insulation film, and a peripheral edge portion of the cutout or a peripheral edge portion of the opening, which is a part of the partial electrode, receives light of an edge portion of the laser spot.

According to this configuration, the center portion of a laser spot, which has a relatively high intensity, passes through the opening portion of the cutout or the like to fall upon the insulation film and securely forms the contact hole. On the other hand, light of the edge portion of the laser spot, which falls upon the peripheral edge portion of the cutout or the like, has a lower intensity compared with the intensity at the center portion of the laser spot and thus does not cause the partial electrode to be melted excessively to be scattered. As a result, a part of the partial electrode is fused securely to the capacitor signal line via the contact hole.

Furthermore, preferably, a superimposition portion where the peripheral edge portion of the cutout or the peripheral edge portion of the opening and the edge portion of the laser spot are superimposed on each other has a surrounding shape (an L shape, a V shape, a U shape, a C shape, or an O shape) that surrounds the opening portion of the cutout or the opening portion of the opening.

According to this configuration, the opening portion of the cutout or the like in the partial electrode is irradiated with the center portion of a laser spot, and the peripheral edge portion of the cutout or the like in the partial electrode is irradiated with the edge portion of the laser spot.

It can be said that a display panel including the active matrix substrate configured as above is also encompassed by the present invention. Furthermore, it can also be said that a display device including the display panel thus configured is also encompassed by the present invention.

Furthermore, there is provided a laser light irradiation method for irradiating a part of an active matrix substrate with laser light so that the active matrix substrate is supplied with laser energy. The active matrix substrate includes: a substrate; a switching element mounted to the substrate; a gate signal line connected to a gate electrode of the switching element; a source signal line connected to a source electrode of the switching element; a drain electrode of the switching element; a partial electrode that is a part of the drain electrode; a capacitor signal line opposed to the partial electrode; and an insulation film interposed between the partial electrode and the capacitor signal line. In the method, the amount of laser energy received by the insulation film is made to vary depending on whether or not the laser light is blocked by the partial electrode.

According to this configuration, the amount of laser energy received by one part of the insulation film, which is covered with the partial electrode, is different from the amount of laser energy received by another part of the insulation film, which is not covered with the partial electrode. In other words, the partial electrode absorbs laser energy supplied to one part of the insulation film, so that there occurs a difference between the amount of laser energy received by the one part of the insulation film, which is covered with the partial electrode, and the amount of laser energy received by another part of the insulation film (a part of the insulation film, which is not covered with the partial electrode). As a result, even in a case of using laser light having a constant intensity, a member irradiated with the laser light can be supplied with various levels of laser energy, and thus the supply of laser energy suitable for required processing can be achieved.

For example, preferably, one part of laser light, which has passed through a portion of the partial electrode, which passes light therethrough instead of blocks it, supplies laser energy to the insulation film so that a contact hole is formed in the insulation film, and by the action of laser energy of the other part of the laser light, which falls upon a portion of the partial electrode, which blocks light, a part of the partial electrode is melted to flow through the contact hole, and thus the partial electrode is fused to the capacitor signal line.

According to this configuration, a part of the partial electrode is fused securely to the capacitor signal line via the contact hole, and thus in place of a source signal, a signal flowing through the capacitor signal line is supplied to the pixel, so that the occurrence of a bright spot is suppressed.

Furthermore, preferably, the portion of the partial electrode, which blocks light, is irradiated with an edge portion of a laser spot, and the portion of the partial electrode, which passes light therethrough instead of blocking it, is irradiated with a center portion of the laser spot.

According to this configuration, the center portion of a laser spot, which has a relatively high intensity, falls upon the insulation film without the partial electrode interposed therebetween and securely forms the contact hole. On the other hand, the edge portion of the laser spot, which has a relatively low laser light intensity, falls upon the partial electrode, and thus, without being melted excessively to be scattered, the partial electrode is fused securely to the capacitor signal line via the contact hole.

The bottom line is that, based on whether or not laser light is blocked by the partial electrode and on a difference in intensity in the intensity distribution of the laser light itself, the supply of laser energy suitable for required processing can further be achieved. As a result of this, in place of a source signal, a signal flowing through the capacitor signal line is supplied to the pixel, so that the occurrence of a bright spot or the like is suppressed.

Preferably, a cutout or an opening is formed in the partial electrode. In this case, the portion of the partial electrode, which blocks light, is a peripheral edge portion of the cutout or a peripheral edge portion of the opening, and the portion of the partial electrode, which passes light therethrough instead of blocking it, is an opening portion of the cutout or an opening portion of the opening.

Furthermore, preferably, the peripheral edge portion of the cutout or the peripheral edge portion of the opening is irradiated with the edge portion of the laser spot so that an irradiated portion of the peripheral edge portion of the cutout or the peripheral edge portion of the opening has a surrounding shape (for example, an L shape, a V shape, a U shape, a C shape, or an O shape) that surrounds the opening portion of the cutout or the opening portion of the opening.

### Advantageous Effects of the Invention

According to the present invention, when an active matrix substrate is irradiated with laser light, the amount of laser energy received by a member irradiated therewith can be made to vary. Thus, the supply of laser energy suitable for required processing can be achieved.

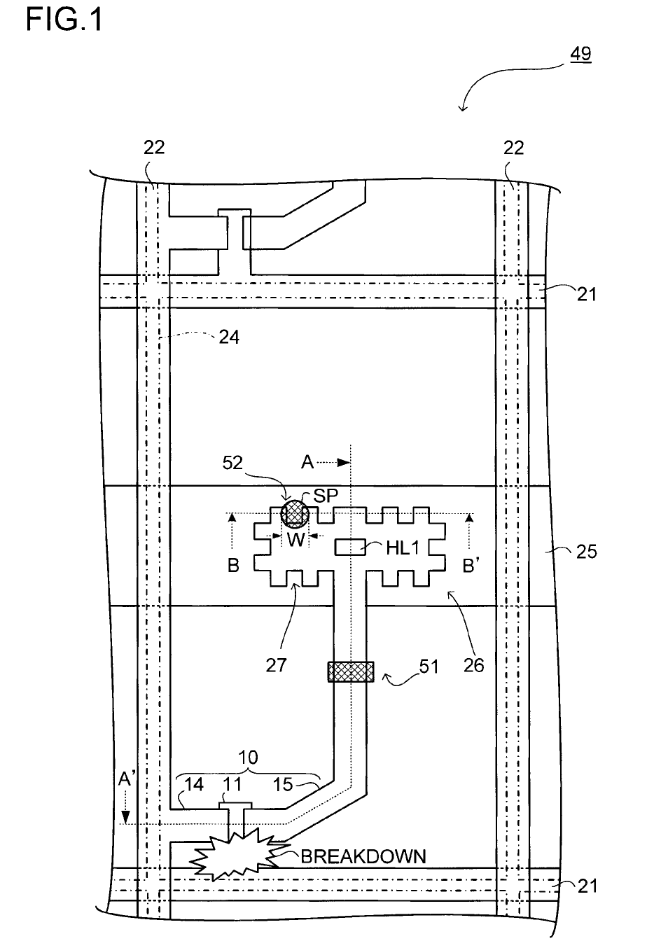

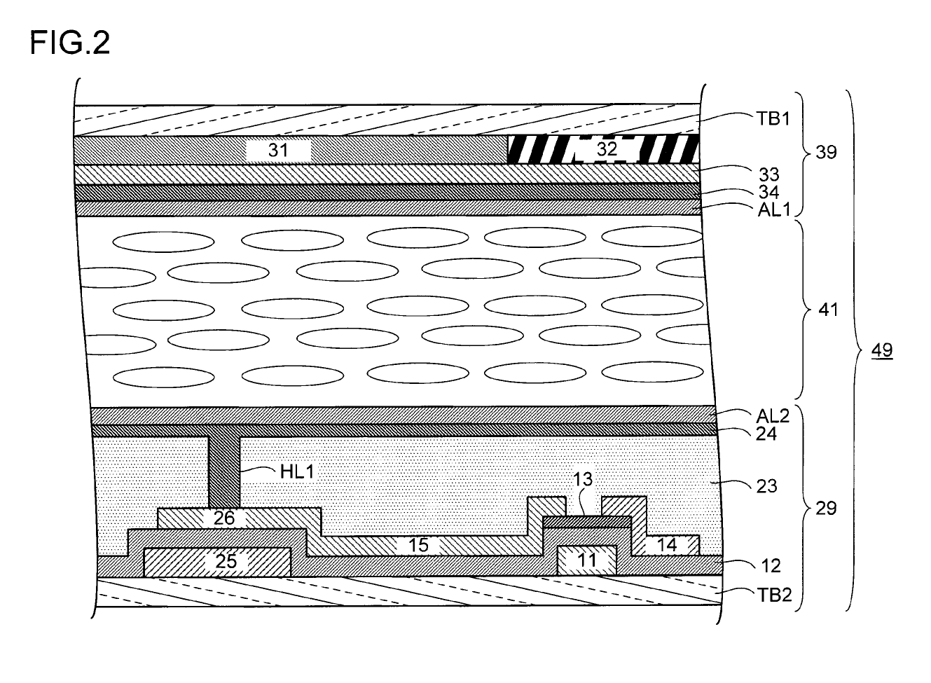

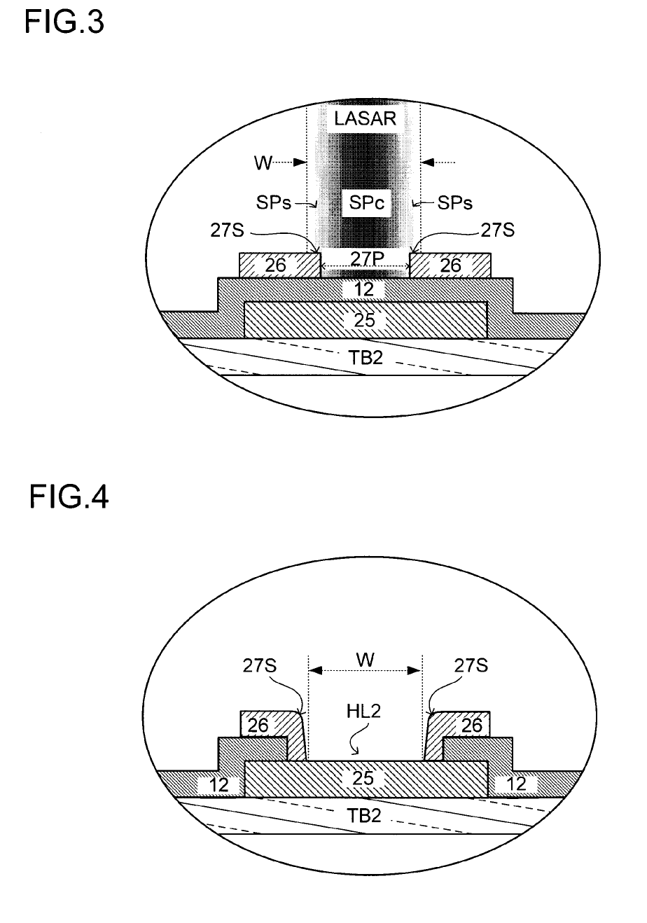

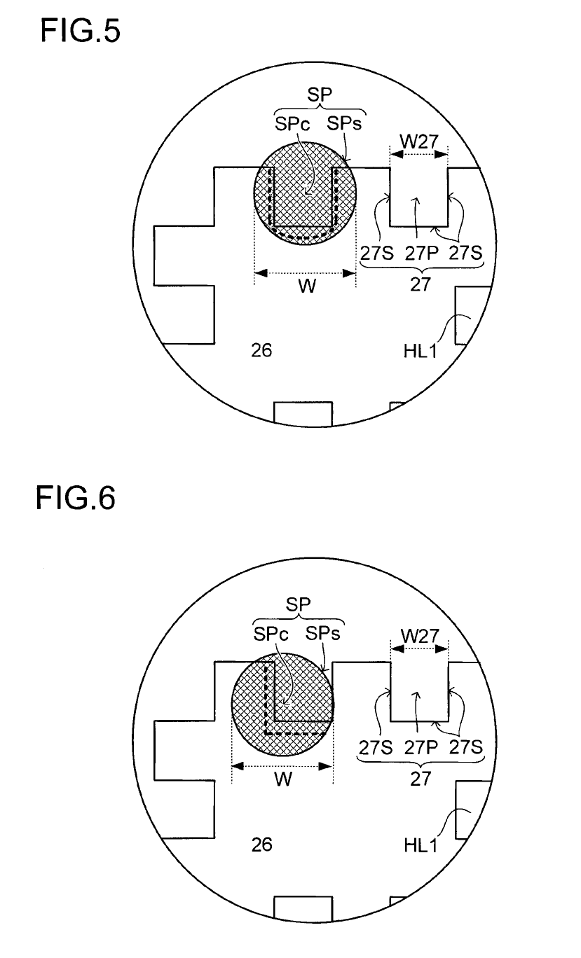

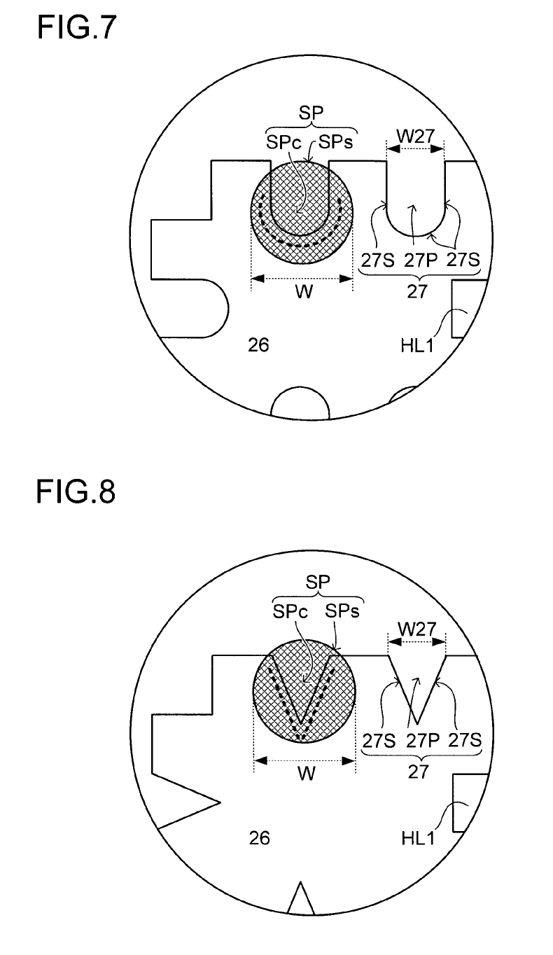

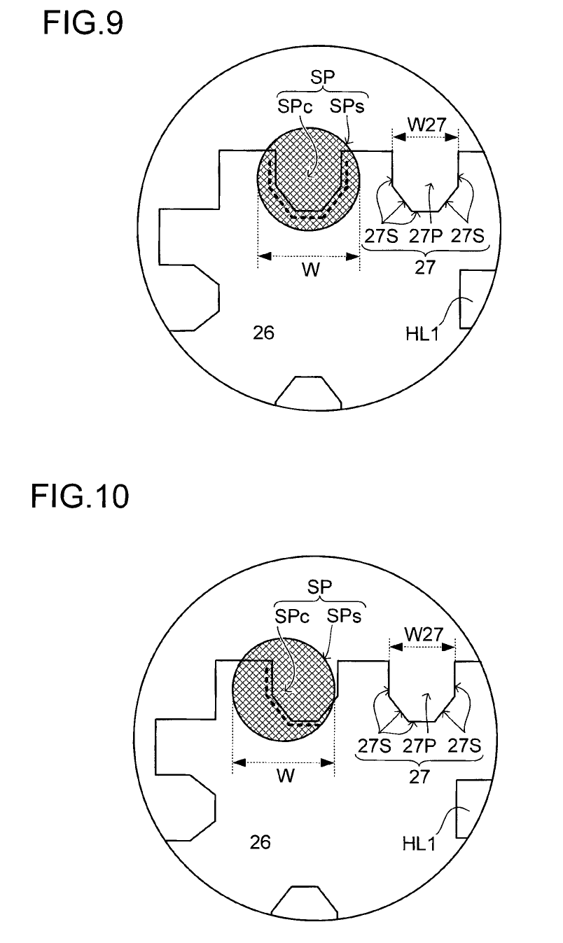

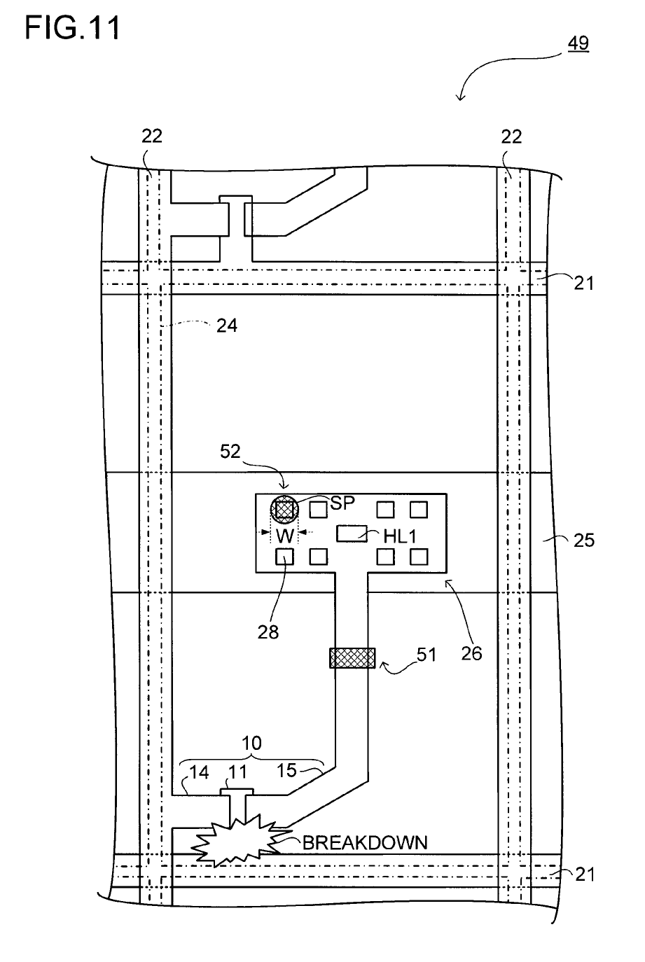

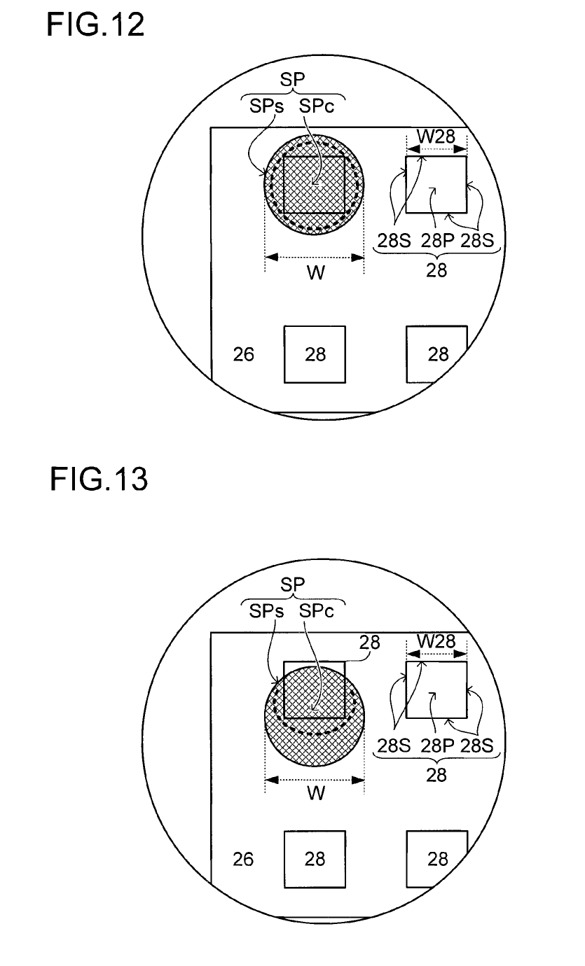

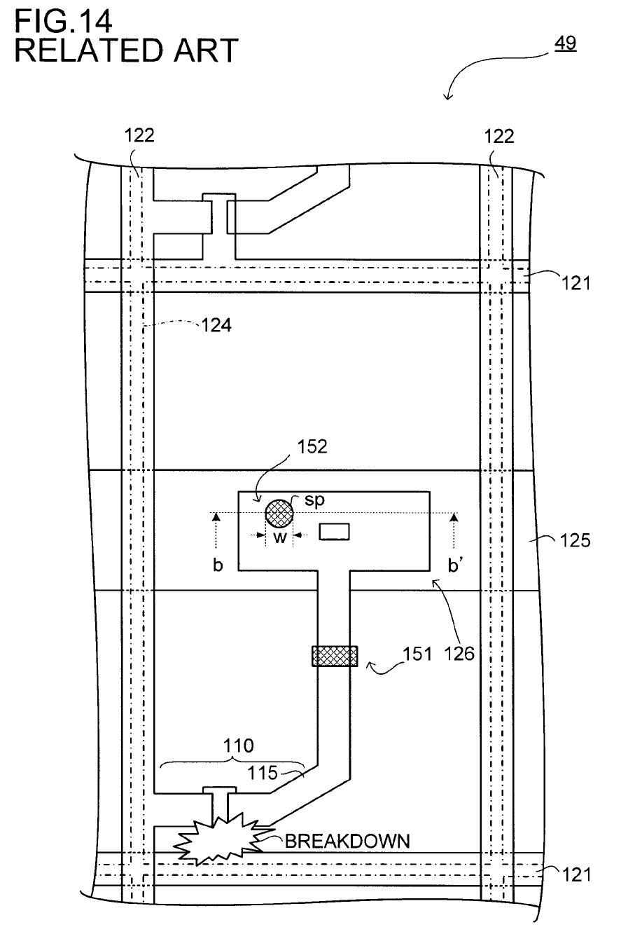

### BRIEF DESCRIPTION OF DRAWINGS

[FIG. 1] is a partial plan view of a liquid crystal display panel.

[FIG. 2] is a partial cross-sectional view of the liquid crystal display panel shown in FIG. 1, which is taken on line A-A′ in a direction of arrows.

[FIG. 3] is a partial cross-sectional view of the liquid crystal display panel shown in FIG. 1, which is taken on line B-B′ in the direction of arrows.

[FIG. 4] is a cross-sectional view showing the liquid crystal display panel with a second contact hole or the like formed therein by laser light irradiation.

[FIG. 5] is a partial enlarged view of the view of FIG. 1.

[FIG. 6] shows a case, as another example of the case of FIG. 5, where a laser spot is formed at a position different from the position shown in FIG. 5.

[FIG. 7] shows a case, as another example of the case of FIG. 5, where a peripheral edge portion of a cutout has a shape different from the shape shown in FIG. 5.

[FIG. 8] shows a case, as another example of the cases of FIGS. 5 to 7, where the peripheral edge portion of the cutout has a shape different from the shapes shown in FIGS. 5 to 7.

[FIG. 9] shows a case, as another example of the cases of FIGS. 5 to 8, where the peripheral edge portion of the cutout has a shape different from the shapes shown in FIGS. 5 to 8.

[FIG. 10] shows a case, as another example of the case of FIG. 9, where a laser spot is formed at a position different from the position shown in FIG. 9.

[FIG. 11] is a partial plan view of a liquid crystal display panel including an auxiliary capacitor electrode with openings formed therein.

[FIG. 12] is a partial enlarged view of the view of FIG. 11.

[FIG. 13] shows a case, as another example of the case of FIG. 12, where a laser spot is formed at a position different from the position shown in FIG. 12.

[FIG. 14] is a partial plan view showing a conventional liquid crystal display panel.

[FIG. 15] is a partial cross-sectional view of the liquid crystal display panel shown in FIG. 14, which is taken on line b-b′ in the direction of arrows.

[FIG. 16] is a cross-sectional view showing the conventional liquid crystal display panel with a contact hole or the like formed therein by laser light irradiation.

[FIG. 17] is a cross-sectional view showing the conventional liquid crystal display panel in a case where a contact hole has failed to be formed therein by laser light irradiation.

### DESCRIPTION OF EMBODIMENTS

### Embodiment 1

The following describes one embodiment with reference to the appended drawings. For the sake of convenience, hatching, reference signs of members, and the like may be omitted in any of the drawings, in which case reference should be made to the other drawings.

A liquid crystal display device includes a backlight unit that is an illuminator and a liquid crystal display panel that is capable of image display upon receiving light from the backlight unit. As shown in a partial plan view of FIG. 1 and a partial cross-sectional view of FIG. 2 (cross-sectional view taken on line A-A′ in the direction of arrows in FIG. 1), in a liquid crystal display panel 49, liquid crystal 41 is sandwiched between a color filter substrate 39 and an active matrix substrate 29 (an unshown spacer for securing space for sandwiching the liquid crystal 41 is sandwiched between the color filter substrate 39 and the active matrix substrate 29).

The color filter substrate 39 includes a first transparent substrate TB1, a color filter 31, a black matrix 32, an overcoat layer 33, a common electrode 34, and a first alignment film AL1.

The first transparent substrate TB1 is a substrate having an insulation property and a transmission property and serves as a base for the color filter substrate 39. There is no particular limitation on a material of the first transparent substrate TB1, and as the material, for example, glass or a resin may be used.

The color filter 31 is a filter that overlaps one surface of the first transparent substrate TB1, which faces toward the liquid crystal 41, and thereby transmits therethrough light traveling to the outside after passing through the liquid crystal 41. That is, the color filter 31 transmits light therethrough and thereby supplies the light in a colored state to the outside. One example of the color filter 31 is any of color filters corresponding to three primary colors of light, i.e., red (R), green (G), and blue (B).

A red color filter 31R, a green color filter 31G, and a blue color filter 31B are arranged in a given pattern. Examples of how they are arranged include a delta arrangement in which the color filters 31R, 31G, and 31B are arranged in a triangular formation, a stripe arrangement in which the color filters 31R, 31G, and 31B are arranged alternately in a row, and a mosaic arrangement in which the color filters 31R, 31G, and 31B are arranged in a mosaic formation.

Similarly to the color filter 31, the black matrix 32 overlaps the one surface of the first transparent substrate TB1, which faces toward the liquid crystal 41. The black matrix 32, however, functions to individually enclose the color filters 31 of the respective colors so as to separate them from one another (each partial region obtained by the separation constitutes a single pixel).

The black matrix 32 is made of a metal having reflectivity (for example, aluminum, chromium, or silver). Thus, in no case is light transmitted from one of the color filters 31 to another adjacent thereto through a boundary therebetween. That is, the black matrix 14 secures a property of blocking light travel from one pixel to another adjacent thereto (color mixing of light is prevented).

The overcoat layer 33 is, for example, an acrylic resin layer. The overcoat layer 33 overlaps the color filter 31 and the black matrix 32 and thereby protects them.

The common electrode 34 is a transparent conductive electrode that faces the liquid crystal 41 while overlapping the overcoat layer 33. The common electrode 34 sandwiches the liquid crystal 41 between itself and an after-mentioned pixel electrode 24 of the active matrix substrate 29 and applies a control voltage to the liquid crystal 41 (a signal supplied to the common electrode is referred to as a common signal). There is no particular limitation on a material of the common electrode 34, and as the material, for example, ITO (indium tin oxide) is used.

The first alignment film AL1 is a film that overlaps the common electrode 34 and thus comes in direct contact with the liquid crystal 41. The first alignment film AL1 sandwiches the liquid crystal 41 between itself and an after-mentioned second alignment film AL2 of the active matrix substrate 29 and aligns molecules of the liquid crystal 41 in a given orientation.

Next, the following describes the active matrix substrate 29. The active matrix substrate 29 includes a second transparent substrate TB2, a gate signal line 21, a source signal line 22, a TFT (thin film transistor) 10, an interlayer insulation film 23, the pixel electrode 24, the second alignment film AL2, and a capacitor signal line 25.

Similarly to the first transparent substrate TB1 of the color filter substrate 39, the second transparent substrate (substrate) TB2 is a substrate having an insulation property and a transmission property. The second transparent substrate TB2 serves as a base for the active matrix substrate 29. Similarly to the first transparent substrate TB1, there is no particular limitation on a material of the second transparent substrate TB2, and as the material, for example, glass or a resin may be used.

The gate signal line 21 is a lead for supplying, under the control of an unshown gate driver, a gate signal that is a control signal to the TFT 10. The gate signal lines 21 are arranged in a row on one surface of the second transparent substrate TB2, which faces the liquid crystal 41.

The source signal line 22 is a lead for supplying, under the control of an unshown source driver, a source signal (image data) to each pixel via the TFT 10. The source signal lines 22 are arranged in a row in a direction intersecting the direction in which the gate signal lines 21 are arranged. Thus, a region divided along both the source signal line 22 and the gate signal line 21 is in a matrix form, and each partial region of the region obtained by the division constitutes each pixel.

The TFT 10 is a semiconductor switching element that is formed in the vicinity of each intersection between the source signal line 22 and the gate signal line 21 and controls an operation of each pixel. That is, the TFT 10 is a transistor for image data writing. The TFT (switching element) 10 includes a gate electrode 11, a gate insulation film 12, a semiconductor layer 13, a source electrode 14, and a drain electrode 15.

The gate electrode 11 is constituted by a part of the gate signal line 21. The gate electrode 11 is therefore formed on the one surface of the second transparent substrate TB2, which faces the liquid crystal 41 (the gate electrode 11 protrudes from the gate signal line 21 in the same direction as the extending direction of the source signal line 22; see FIG. 1).

The gate insulation film (insulation film) 12 is so formed as to cover the gate electrode 11 and prevents the occurrence of a leakage current.

The semiconductor layer 13 is formed on the gate electrode 11 via the gate insulation film 12. Utilizing the characteristics of the semiconductor layer 13, the TFT 10 controls the flow of a source signal in accordance with a voltage applied to the gate electrode 11. The semiconductor layer 13 is made of, for example, amorphous silicon but is not limited thereto.

The source electrode 14 is so formed as to cover the semiconductor layer 13 and the gate insulation film 12 and is constituted by a part of the source signal line 22 (the source electrode 14 protrudes from the source signal line 22 in the same direction as the extending direction of the gate signal line 21; see FIG. 1).

Similarly to the source electrode 14, the drain electrode 15 is so formed as to cover the semiconductor layer 13 and the gate insulation film 12. That is, the drain electrode 15 and the source electrode 14 face each other on the semiconductor layer 13 and the gate insulation film 12. The flow of a current from the source electrode 14 to the drain electrode 15 is controlled in accordance with a voltage applied to the gate electrode 11. The drain electrode 15 is so extended as to overlap the after-mentioned capacitor signal line 25 (which will be detailed later).

The interlayer insulation film 23 covers the TFT 10 and thereby secures insulation between the TFT 10 and so on and the other members (for example, the pixel electrode 24). Furthermore, the interlayer insulation film 23 also serves to form the pixel electrode 24 in a flat shape by covering asperities on the TFT 10.

Similarly to the common electrode 34, the pixel electrode 24 is an electrode made of, for example, ITO and overlaps the flat-shaped interlayer insulation film 23. Via a first contact hole HL1 formed in the interlayer insulation film 23, conduction is established between the pixel electrode 24 and the drain electrode 15 (more specifically, an after-mentioned auxiliary capacitor electrode 26). Thus, when the TFT is turned on, a source signal flows to the pixel electrode 24 via the drain electrode 15, and when the TFT is turned off, the supply of a source signal to the pixel electrode 24 is cut off.

That is, in accordance with voltage application to the pixel electrode 24, a voltage to be applied to the liquid crystal 41 sandwiched between the pixel electrode 24 and the common electrode 34 is controlled (the pixel electrode 24 and the common electrode 34 sandwiching the liquid crystal 41 therebetween form a liquid crystal capacitor).

The second alignment film AL2 is a film that overlaps the pixel electrode 24 and thus comes in direct contact with the liquid crystal 41. The second alignment film AL2 sandwiches the liquid crystal 41 between itself and the first alignment film AL1 of the color filter substrate 39 and aligns the molecules of the liquid crystal 41 in a given orientation.

The capacitor signal line 25 is a lead for a signal for forming an auxiliary capacitor to flow therethrough, and the capacitor signal lines 25 are arranged in the same direction as the direction in which the gate signal lines 21 are arranged so that each of them is positioned between each pair of adjacent ones of the gate signal lines 21 enclosing each pixel therebetween. Furthermore, similarly to the gate electrode 11 and the gate signal line 21, the capacitor signal line 25 is formed on the one surface of the second transparent substrate TB2, which faces the liquid crystal 41, and is covered with the gate insulation film 12.

One end 26 (one end not connected to the TFT 10) of the drain electrode 15 extends to overlap the capacitor signal line 25. The capacitor signal line 25 and the one end 26 of the drain electrode 15 therefore face each other via the gate insulation film 12 serving as a dielectric layer and form an auxiliary capacitor (the one end 26 of the drain electrode 15 is referred to as an auxiliary capacitor electrode 26).

Based on the above, the liquid crystal display panel 49 having a multilayer lamination structure in which the two substrates TB1 and TB2 sandwich the liquid crystal (for example, nematic liquid crystal) 41 therebetween performs image display in the following manner.

That is, in the above-described liquid crystal display panel 49, when the TFT 10 is turned on based on a gate signal voltage given via the gate signal line 21, a source signal voltage on the source signal line 22 is given to the pixel electrode 24 via the source electrode 14 and the drain electrode 15 of the TFT 10. In accordance with the source signal voltage, a voltage value of the source signal voltage is written into the liquid crystal (liquid crystal capacitor) sandwiched between the pixel electrode 24 and the common electrode 34.

On the other hand, when the TFT 10 is off, a source signal voltage remains held by the liquid crystal capacitor and the auxiliary capacitor (until a new source signal voltage is applied next, the source signal voltage is held by the liquid crystal capacitor and the auxiliary capacitor). That is, the TFT 10 is turned on and off repeatedly, and thus the liquid crystal 41 is made to vary in the amount of light transmitted therethrough, so that images are displayed on the liquid crystal display panel 49.

The above-described liquid crystal display panel 49 then undergoes a pre-delivery inspection for checking whether or not there is any defective pixel. In this inspection, first, a voltage to bring the liquid crystal 41 to a black display state is applied to the liquid crystal display panel 49 in a normally white mode via the pixel electrode 24 and the common electrode 34. Then, among pixels supposed to have been brought to the black display state, any pixel that has become a bright spot is detected as a defect (this inspection may be performed by viewing with the human eye or by using a device that automatically detects a bright spot).

There are various factors that could cause a pixel to malfunction and thus become a bright spot. For example, such a malfunction occurs if, in fabricating the TFT 10, the gate insulation film 12 is contaminated by dust or there remains a part of the semiconductor layer 13 and/or a part of the pixel electrode 24, which should have been removed by patterning.

If, for example, as shown in FIG. 1, a breakdown occurs at a part of one TFT 10 and thus a source signal is not supplied to the pixel electrode 24 via the drain electrode 15, for example, a voltage to bring about a black display state is not applied appropriately to the liquid crystal 41 of a pixel controlled by the one TFT 10, so that the pixel becomes a bright spot (defect).

In order, therefore, to suppress the occurrence of a bright spot, a configuration is adopted in which, in place of a source signal, a signal flowing through the capacitor signal line 25 is supplied to the pixel electrode 24 via the drain electrode 15 (a method for achieving this may be referred to as a defect correction method). The reason for this is that, with this configuration, the pixel electrode 24 receives the supply of a signal flowing through the capacitor signal line 25 and is thus capable of, together with the common electrode 34, applying a voltage to the liquid crystal 41.

In order that a signal of the capacitor signal line 25 may be supplied to the pixel electrode 24, a part of the active matrix substrate 29 is irradiated with laser light in the following manner. That is, first, using laser light, for example, laser light having a wavelength of 1064 nm from a YAG laser, the drain electrode 15 is cut at a part thereof between the auxiliary capacitor electrode 26 and the TFT 10 (the cut part is denoted by number 51). This securely cuts off the supply of a source signal to the pixel electrode 24.

Next, laser light irradiation is performed with respect to the auxiliary capacitor electrode 26 overlapping the capacitor signal line 25 via the gate insulation film 12 (when seen from a direction perpendicular to the in-plane direction of the liquid crystal display panel 49, the capacitor signal line 25 has an area sufficient to include the area of the auxiliary capacitor electrode 26). More specifically, an outer edge portion of the auxiliary capacitor electrode 26, which overlaps the capacitor signal line 25, is irradiated with laser light (a region irradiated with the laser light is denoted by number 52).

In this case, however, a cutout 27 is formed in this outer edge portion of the auxiliary capacitor electrode (partial electrode) 26 (more specifically, the cutouts 27 are formed in a collected manner, so that the outer edge portion is shaped like comb teeth). Thus, as shown in FIG. 3 that is a cross-sectional view taken on line B-B′ in the direction of arrows in FIG. 1, one part of the laser light (one part of a laser spot SP) passes through an opening portion 27P of the cutout 27 and reaches the gate insulation film 12. Furthermore, the other part of the laser light reaches a peripheral edge portion 27S of the cutout 27 in the auxiliary capacitor electrode 26.

With this configuration, the amount of laser energy received by the gate insulation film 12 varies depending on whether or not laser light is blocked by the auxiliary capacitor electrode 26. More specifically, the amount of laser energy received by one part of the gate insulation film 12, which is covered with the auxiliary capacitor electrode 26, is different from the amount of laser energy received by another part of the gate insulation film 12, which is not covered with the auxiliary capacitor electrode 26.

The bottom line is that the auxiliary capacitor electrode 26 absorbs laser energy supplied to one part of the gate insulation film 12, so that there occurs a difference between the amount of laser energy received by the one part of the gate insulation film 12, which is covered with the auxiliary capacitor electrode 26, and the amount of laser energy received by another part of the gate insulation film 12 (a part of the gate insulation film 12, which is not covered with the auxiliary capacitor electrode 26). As a result, even in a case of using laser light having a constant intensity, a member irradiated with the laser light can be supplied with various levels of laser energy, and thus the supply of laser energy suitable for required processing can be achieved.

For example, in order to prevent the auxiliary capacitor electrode 26 from being melted excessively to be scattered, the laser light intensity is set to a relatively low level. If the laser light intensity is too low, however, a second contact hole HL2 for establishing a connection (for causing a short circuit) between the auxiliary capacitor electrode 26 and the capacitor signal line 25 may not be formed in the gate insulation film 12 covered with the auxiliary capacitor electrode 26.

In a case, however, where the cutout 27 is formed in the auxiliary capacitor electrode 26, laser light having such an intensity as not to cause excessive melting of the auxiliary capacitor electrode 26 is applied toward the cutout 27. With this configuration, the peripheral edge portion 27S (a portion of the partial electrode, which blocks light) of the cutout 27, upon which the laser spot SP falls, is melted to a moderate degree.

On the other hand, one part of the laser spot SP, which falls upon the opening portion 27P (a portion of the partial electrode, which passes light therethrough instead of blocking it) of the cutout 27, supplies laser energy to the gate insulation film 12 without the auxiliary capacitor electrode 26 interposed therebetween, and thus a relatively high level of laser energy is supplied to the gate insulation film 12. This secures the formation of the second contact hole HL2 in the gate insulation film 12.

The bottom line is that, as shown in FIG. 3 and FIG. 4 (a view showing a state after laser light irradiation shown in FIG. 3 is performed), one part of laser light, which has passed through the opening portion 27P of the cutout 27 in the auxiliary capacitor electrode 26, supplies laser energy to the gate insulation film 12, and thus the second contact hole HL2 is formed securely in the gate insulation film 12.

Furthermore, by the action of laser energy of the other part of the laser light, which falls upon the peripheral edge portion 27S of the cutout 27 in the auxiliary capacitor electrode 26, the peripheral edge portion 27S is melted to flow through the second contact hole HL2 and is fused securely to the capacitor signal line 25 (since the auxiliary capacitor electrode 26 in a melted state surrounds the second contact hole HL2, a melted part of the auxiliary capacitor electrode 26 tends to flow into the second contact hole HL2, and thus the auxiliary capacitor electrode 26 is likely to be short-circuited with the capacitor signal line 25). As a result, in place of a source signal, a signal flowing through the capacitor signal line 25 is supplied to the pixel electrode 24 (i.e. a pixel), so that the occurrence of a bright spot is suppressed.

In other words, even if the number of times laser light irradiation is performed is small, defect correction is achieved securely (furthermore, even if an oscillator of a laser used operates in an unstable manner, defect correction is likely to be achieved). Thus, in this laser light irradiation method, without the need to set the laser throughput to be excessively high, a defective pixel is corrected in a short period of time at low cost by securely fusing a part (the peripheral edge portion 27S) of the auxiliary capacitor electrode 26 to the capacitor signal line 25 via the second contact hole HL2. This improves the yield of the active matrix substrate 29, and accordingly, the yield of the liquid crystal display panel 49.

Moreover, in a case where a part of the auxiliary capacitor electrode 26 and the capacitor signal line 25 are fused together by laser light irradiation, since a cutout width W27 of the cutout 27 is smaller than a diameter (laser spot diameter; symbol W) of the laser spot SP, the opening portion 27P of the cutout 27 passes light of a center portion SPc of the laser spot SP therethrough to guide it to the gate insulation film 12, and the peripheral edge portion 27S of the cutout 27 receives light of an edge portion SPs of the laser spot SP.

In other words, the peripheral edge portion 27S in the auxiliary capacitor electrode 26, which blocks light, is irradiated with the edge portion SPs of the laser spot SP, and the opening portion 27P in the auxiliary capacitor electrode 26, which passes light therethrough instead of blocking it, is irradiated with the center portion SPc of the laser spot SP.

With this configuration, the center portion SPc of the laser spot SP, which has a relatively high intensity, falls upon the gate insulation film 12 without the auxiliary capacitor electrode 26 interposed therebetween and securely forms the second contact hole HL2. On the other hand, the edge portion SPs of the laser spot SP, which has a relatively low laser light intensity, falls upon the peripheral edge portion 27S of the cutout 27 in the auxiliary capacitor electrode 26, and thus, without being melted excessively to be scattered, the peripheral edge portion 27S is fused securely to the capacitor signal line via the second contact hole HL2 (in FIG. 3, laser light is shown to have densely shaded and less densely shaded portions, and the densely shaded portion represents a portion having a laser light intensity higher than that of the less densely shaded portion).

The bottom line is that, based on whether or not laser light is blocked by the auxiliary capacitor electrode 26 and on a difference in intensity in the intensity distribution of the laser light itself, the supply of laser energy suitable for required processing can further be achieved. As a result of this, the second contact hole HL2 can be formed securely, and a short circuit between the auxiliary capacitor electrode 26 and the capacitor signal line 25 can be caused securely.

In order that the opening portion 27P of the cutout 27 in the auxiliary capacitor electrode 26 may be irradiated with the center portion SPc of the laser spot SP and that the peripheral edge portion 27S of the cutout 27 in the auxiliary capacitor electrode 26 may be irradiated with the edge portion SPs of the laser spot SP, any of the following configurations is adopted.

That is, a superimposition portion where the peripheral edge portion 27S of the cutout 27 and the edge portion SPs of the laser spot SP are superimposed on each other may have a U shape surrounding the opening portion 27P of the cutout 27 (see an extra-thick dashed line in FIG. 5) or an L shape (see an extra-thick dashed line in FIG. 6).

Furthermore, the shape of the superimposition portion changes with a change in the shape of the peripheral edge portion 27S of the cutout 27. For example, as shown in FIG. 7, in a case where a part of the peripheral edge portion 27S, which corresponds to the bottom of the cutout 27, is bent, the superimposition portion is likely to have a C shape. Furthermore, as shown in FIG. 8, in a case where the part of the peripheral edge portion 27 S, which corresponds to the bottom of the cutout 27, is tapered, the superimposition portion is likely to have a V shape.

Furthermore, as shown in FIGS. 9 and 10, the part of the peripheral edge portion 27S, which corresponds to the bottom of the cutout 27, may have a shape having a bent point. In such a case, the superimposition portion is set to have such a shape as to be able to surround the opening portion 27S of the cutout 27 (see extra-thick dashed lines in FIGS. 9 and 10).

### Other Embodiments

The present invention is not limited to the above-described embodiment and can be changed variously without departing from the spirit of the invention.

For example, although the foregoing describes a case where the cutout 27 is formed in the auxiliary capacitor electrode 26, there is no limitation thereto. As shown in the partial plan view of FIG. 11, an opening 28 may be formed in an auxiliary capacitor electrode 26. The reason for this is that, in this case, based on the fact that one part of laser light passes through the opening 28 and the other part of the laser light does not pass through the opening 28, i.e. based on whether or not laser light is blocked by the auxiliary capacitor electrode 26, the amount of laser energy received by a gate insulation film 12 is made to vary (the bottom line is that, even in a case of using laser light having a constant intensity, a member irradiated with the laser light can be supplied with various levels of laser energy, and thus the supply of laser energy suitable for required processing can be achieved).

Thus, also with respect to an active matrix substrate 29 including the auxiliary capacitor electrode 26 having the opening 28, a defect correction can be performed in a similar manner as in the case of the active matrix substrate 29 including the auxiliary capacitor electrode 26 having the cutout 27.

That is, one part of laser light that has passed through the opening 28 in the auxiliary capacitor electrode 26, which passes light therethrough, supplies laser energy to the gate insulation film 12, and thus a second contact hole HL2 is formed in the gate insulation film 12. Furthermore, by the action of laser energy of the other part of the laser light, which falls upon a portion of the auxiliary capacitor electrode 26, which blocks light (a peripheral edge portion 28S of the opening 28), the peripheral edge portion 28S is melted to flow through the second contact hole HL2, and thus the auxiliary capacitor electrode 26 is fused to a capacitor signal line 25. Thus, in place of a source signal, a signal flowing through the capacitor signal line 25 is supplied to a pixel electrode 24, so that the occurrence of a bright spot is suppressed.

Furthermore, in a case where an opening width W28 of the opening 28 is smaller than a diameter of a laser spot SP, an opening portion 28P (a portion of a partial electrode, which passes light therethrough instead of blocking it) of the opening 28 in the auxiliary capacitor electrode 26 passes light of a center portion SPc of the laser spot SP therethrough to guide it to the gate insulation film 12. Moreover, the peripheral edge portion 28S (a portion of the partial electrode, which blocks light) of the opening 28 in the auxiliary capacitor electrode 26 receives light of an edge portion SPs of the laser spot SP.

That is, similarly to the case of the cutout 27, the center portion SPc of the laser spot SP, which has a relatively high intensity, falls upon the gate insulation film 12 without the auxiliary capacitor electrode 26 interposed therebetween and securely forms the second contact hole HL2. On the other hand, the edge portion SPs of the laser spot SP, which has a relatively low laser light intensity, falls upon the peripheral edge portion 28S of the opening 28 in the auxiliary capacitor electrode 26, and thus, without being melted excessively to be scattered, the peripheral edge portion 28S is fused securely to the capacitor signal line 25 via the second contact hole HL2.

Furthermore, as shown in FIGS. 12 and 13, in order that the opening portion 28P of the opening 28 in the auxiliary capacitor electrode 26 may be irradiated with the center portion SPc of the laser spot SP and that the peripheral edge portion 28S of the opening 28 in the auxiliary capacitor electrode 26 may be irradiated with the edge portion SPs of the laser spot SP, any of the following configurations is adopted.

That is, a superimposition portion where the peripheral edge portion 28S of the opening 28 and the edge portion SPs of the laser spot SP are superimposed on each other may have an O shape surrounding the opening portion 28P of the opening 28 (see an extra-thick dashed line in FIG. 12) or a C shape (see an extra-thick dashed line in FIG. 13). The bottom line is that the superimposition portion is set to have such a shape as to be able to surround the opening portion 28P of the opening 28.

In other words, preferably, the peripheral edge portion 27S of the cutout 27 or the peripheral edge portion 28S of the opening 28 is irradiated with the edge portion SPs of the laser spot SP so that a thus irradiated portion thereof has a surrounding shape (for example, an L shape, a V shape, a U shape, a C shape, or an O shape) that surrounds the opening portion 27P of the cutout 27 or the opening portion 28P of the opening 28.

The auxiliary capacitor electrode 26 may have a single or a plurality of openings 28 or cutouts 27 formed therein. The reason for this is that, if there is at least one opening 28 or cutout 27, when the opening 28 or the cutout 27 is irradiated with the laser spot SP, a member irradiated therewith can be supplied with various levels of laser energy, and thus the supply of laser energy suitable for required processing can be achieved.

Furthermore, by the action of laser energy, the auxiliary capacitor electrode 26 (and accordingly, a drain electrode 15) is melted. There is therefore no particular limitation on a material of the auxiliary capacitor electrode 26 as long as the material is a conductor (for example, a metal) that can be melted by the action of a given level of laser energy. Similarly, the gate insulation film 12 is also melted by the action of laser energy. There is therefore no particular limitation on a material of the gate insulation film 12 as long as the material is an insulator (for example, a resin) that can be melted by the action of a given level of laser energy.

Furthermore, although the foregoing describes a case using a YAG (yttrium aluminum garnet) laser as one example of a laser, there is no limitation thereto, and any other type of laser may be used instead. Furthermore, laser light irradiation may be performed using an automatic-control defect correction device (laser light irradiation device) including a laser oscillator or by any other method.

In a case where an automatic-control defect correction device is used to irradiate the active matrix substrate 29 with laser light, a microcomputer unit incorporated in the defect correction device adjusts a laser light irradiation position (position of the laser spot SP). This adjustment is achieved by executing a laser spot position adjustment program. Furthermore, this program is a computer-executable program and may be recorded on a computer-readable recording medium. The reason for this is that recording the program on a recording medium imparts portability to the program.

A recording medium used in this case is, for example, any of the following: demountable tapes including magnetic tapes, cassette tapes, and the like; disks including magnetic disks and optical disks such as a CD-ROM and the like; cards including IC cards (including a memory card), optical cards, and the like; and semiconductor memories such as a flash memory and the like.

Furthermore, the microcomputer unit may acquire the laser spot position adjustment program through communication from a communication network. Examples of a communication network described here include, regardless of whether they are wired or wireless, the Internet, infrared communication, and so on.

Furthermore, although the foregoing describes a case using a liquid crystal display device as one example of a display device, there is no limitation thereto. For example, a plasma display device, an organic EL (electro-luminescence) display device, or the like may be used instead. The bottom line is that any type of display panel and any type of display device can be used as long as they include the active matrix substrate 29.

### LIST OF REFERENCE SIGNS

10 TFT (switching element)
11 Gate electrode
12 Gate insulation film (insulation film)
HL2 Second contact hole (contact hole)
13 Semiconductor layer
14 Source electrode
15 Drain electrode
21 Gate signal line
22 Source signal line
23 Interlayer insulation film
HL1 First contact hole
24 Pixel electrode
25 Capacitor signal line
26 Auxiliary capacitor electrode (partial electrode)
27 Cutout
27P Opening portion of cutout (portion of partial electrode, which passes light therethrough instead of blocking it)
27S Peripheral edge portion of cutout (portion of partial electrode, which blocks light)
W27 Cutout width
28 Opening
28P Opening portion of opening (portion of partial electrode, which passes light therethrough instead of blocking it)
28S Peripheral edge portion of opening (portion of partial electrode, which blocks light)
W28 Opening width
SP Laser spot
SPc Center portion of laser spot
SPs Edge portion of laser spot
W Diameter of laser spot
TB2 Second transparent substrate (substrate)
AL2 Second alignment film
29 Active matrix substrate
31 Color filter
32 Black matrix
33 Overcoat layer
34 Common electrode
TB1 First transparent substrate
AL1 First alignment film
39 Color filter substrate
49 Liquid crystal display panel

1. An active matrix substrate, comprising:
a substrate;
a switching element mounted to the substrate;
a gate signal line connected to a gate electrode of the switching element;
a source signal line connected to a source electrode of the switching element;
a drain electrode of the switching element;
a partial electrode that is a part of the drain electrode;
a capacitor signal line opposed to the partial electrode; and
an insulation film interposed between the partial electrode and the capacitor signal line,
wherein a cutout or an opening is formed in the partial electrode.

2. The active matrix substrate according to claim 1, wherein
in a case where a part of the partial electrode and the capacitor signal line are fused together by laser light irradiation,
a cutout width of the cutout or an opening width of the opening is set to be smaller than a diameter of a laser spot so that:
an opening portion of the cutout or an opening portion of the opening passes light of a center portion of the laser spot therethrough to guide it to the insulation film; and
a peripheral edge portion of the cutout or a peripheral edge portion of the opening, which is the part of the partial electrode, receives light of an edge portion of the laser spot.

3. The active matrix substrate according to claim 2, wherein
a superimposition portion where the peripheral edge portion of the cutout or the peripheral edge portion of the opening and the edge portion of the laser spot are superimposed on each other has a surrounding shape that surrounds the opening portion of the cutout or the opening portion of the opening.

4. The active matrix substrate according to claim 3, wherein the surrounding shape is an L shape, a V shape, a U shape, a C shape, or an O shape.

5. A display panel comprising the active matrix substrate according to claim 1.

6. A display device comprising the display panel according to claim 5.

7. A laser light irradiation method for irradiating a part of an active matrix substrate with laser light so that the active matrix substrate is supplied with laser energy, the active matrix substrate comprising:
a substrate;
a switching element mounted to the substrate;
a gate signal line connected to a gate electrode of the switching element;
a source signal line connected to a source electrode of the switching element;
a drain electrode of the switching element;
a partial electrode that is a part of the drain electrode;
a capacitor signal line opposed to the partial electrode; and
an insulation film interposed between the partial electrode and the capacitor signal line,
wherein an amount of laser energy received by the insulation film is made to vary depending on whether or not the laser light is blocked by the partial electrode.

8. The laser light irradiation method according to claim 7, wherein
one part of laser light, which has passed through a portion of the partial electrode, which passes light therethrough instead of blocks it, supplies laser energy to the insulation film so that a contact hole is formed in the insulation film, and
by an action of laser energy of the other part of the laser light, which falls upon a portion of the partial electrode, which blocks light, a part of the partial electrode is melted to flow through the contact hole, and thus the partial electrode is fused to the capacitor signal line.

9. The laser light irradiation method according to claim 7, wherein
the portion of the partial electrode, which blocks light, is irradiated with an edge portion of a laser spot, and
the portion of the partial electrode, which passes light therethrough instead of blocking it, is irradiated with a center portion of the laser spot.

10. The laser light irradiation method according to claim 7, wherein
a cutout or an opening is formed in the partial electrode,
the portion of the partial electrode, which blocks light, is a peripheral edge portion of the cutout or a peripheral edge portion of the opening, and
the portion of the partial electrode, which passes light therethrough instead of blocking it, is an opening portion of the cutout or an opening portion of the opening.

11. The laser light irradiation method according to claim 10, wherein
the peripheral edge portion of the cutout or the peripheral edge portion of the opening is irradiated with the edge portion of the laser spot so that an irradiated portion of the peripheral edge portion of the cutout or the peripheral edge portion of the opening has a surrounding shape that surrounds the opening portion of the cutout or the opening portion of the opening.

12. The laser light irradiation method according to claim 11, wherein
the surrounding shape is an L shape, a V shape, a U shape, a C shape, or an O shape.
